(19) United States
(12) Patent Application Publication
(10) Pub. No.: US 2025/0336767 A1
(43) Pub. Date: Oct. 30, 2025

(54) LIQUID COOLING OF AN INTEGRATED CIRCUIT

(71) Applicant: QUALCOMM Incorporated, San Diego, CA (US)

(72) Inventors: Kalyan INAMDAR, Pune (IN); Palkesh JAIN, Bangalore (IN); Nikhil Rajendra PATIL, Bengaluru (IN); Niraj Shantilal PALIWAL, Nasik (IN); Vipul Deepak AHUJA, Bengaluru (IN); Akashdeep GANGRADE, Ludhiana (IN)

(21) Appl. No.: 18/648,792

(22) Filed: Apr. 29, 2024

(51) Int. Cl. H01L 23/473; H01L 25/065

(52) U.S. Cl. CPC H01L 23/473; H01L 25/0655

(57) ABSTRACT

An integrated circuit device that includes a substrate and a first die physically and electrically connected to the substrate. The integrated circuit device includes a manifold that includes a first surface, an inlet port configured as an entry for fluid into a chamber formed between the first die and the manifold, and an outlet port configured to provide an exit from the chamber for the fluid. The integrated circuit device also includes a sealant connecting the first die to the first surface of the manifold to form a seal between the first die and the manifold.

### FIELD

Various features relate to liquid cooling of an integrated circuit.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit (IC). As ICs become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

High electrical performance expected from electronic devices requires heat dissipation systems so that the electronic devices are functional and usable in work environments. Efficiently meeting heat dissipation requirements for high-power ICs of electronic devices, including central processing units and graphics processing units, is becoming increasingly difficult using conventional cooling approaches (e.g., air-cooling and cold plates).

### SUMMARY

Various features relate to IC devices.

One example provides an IC device that includes a substrate and a first die physically and electrically connected to the substrate. The IC device includes a manifold that includes a first surface, an inlet port configured as an entry for fluid into a chamber formed between the first die and the manifold, and an outlet port configured to provide an exit from the chamber for the fluid. The IC device also includes a sealant connecting the first die to the first surface of the manifold to form a seal between the first die and the manifold.

Another example provides a system including a substrate and a first die physically and electrically connected to the substrate. The system includes a manifold that includes an inlet port configured as an entry for fluid into a chamber formed between the first die and the manifold. The manifold includes an outlet port configured to provide an exit from the chamber for the fluid. The system includes a seal for the chamber between the first die and the manifold. The system also includes a lid coupled to the substrate. The fluid ports extend through openings in the lid.

Another example provides a method of forming an IC device that includes connecting a manifold to a first die using a sealant to form a seal between the manifold and the first die. The first die is electrically connected to a substrate. The manifold includes an inlet port to a chamber between the manifold and the first die formed by the seal. The manifold includes an outlet port from the chamber. The method also includes coupling a lid to the substrate to enclose the first die and the manifold. The inlet port and the outlet port extend through openings in the lid.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view, taken substantially along the cutting plane represented by line A-A of FIG. 1B, of an exemplary system that enables liquid cooling of an integrated circuit.

FIG. 1B illustrates a top view representation of the exemplary system that enables liquid cooling of the integrated circuit.

FIG. 2 illustrates a top view representation of the integrated circuit of FIGS. 1A and 1B.

FIG. 3A depicts a bottom view representation of an implementation of a manifold.

FIG. 3B depicts a perspective view representation of the implementation of the manifold of FIG. 3A.

FIG. 3C depicts a cross-sectional profile view, taken substantially along the cutting plane represented by line C-C of FIG. 3A, of the implementation of the manifold of FIG. 3A.

FIG. 4A illustrates a first part of an exemplary sequence for fabricating an exemplary system that enables liquid cooling of an integrated circuit.

FIG. 4B illustrates a second part of the exemplary sequence for fabricating the exemplary system that enables liquid cooling of the integrated circuit.

FIG. 5 illustrates an exemplary flow diagram of a method of fabricating a system that enables liquid cooling of an integrated circuit.

FIG. 6 illustrates various electronic devices that may integrate an exemplary system that enables liquid cooling of an integrated circuit.

### DETAILED DESCRIPTION

In the following description, specific details are given to provide a thorough understanding of the various aspects of the disclosure. However, it will be understood by one of ordinary skill in the art that the aspects may be practiced without these specific details. For example, various devices and structures disclosed herein are illustrated schematically (e.g., in cross-sectional views). Such schematic representations are not to scale and are intentionally simplified. To illustrate, integrated circuit devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

In the context of this disclosure, a “face” of a die (e.g., an integrated circuit) refers to a surface of the die adjacent to an active region of the die. For example, the active region can include various layers and structures that define circuit elements, such as transistors, conductors, passive circuit elements (e.g., resistors, inductors, capacitors, etc.), and a power delivery network. In this example, the face of the die corresponds to the side of the die that bounds the active region. In contrast, a “back” of the die refers to an opposite side of the die which bounds an inactive region of the die. For example, the inactive region typically includes undoped monocrystalline semiconductive material, other inactive layers (e.g., passivation layers), or both.

Particular aspects of the disclosure describe a system that enables direct liquid cooling of an IC (e.g., a high-power IC). The system also enables conductive cooling of one or more devices (e.g., one or more power management ICs, one or more memory devices, etc.) proximate to the IC via thermal contact with a lid. The system includes a manifold that enables liquid cooling of the IC. The IC may be processed to include a support for the manifold and a heat transfer region directly contacted by cooling fluid. The heat transfer region may include channels or fins (e.g., posts or other structures that extend from the IC) that increase a surface area of the IC to facilitate heat transfer from the IC device to the cooling fluid. The processing may be subtractive processing that removes a portion of inactive region of the IC, may be an additive processing that adds material to the back of the IC, or combinations thereof. The system may also include the lid. One or more devices proximate to the IC may be in direct thermal contact with the lid, or may be in thermal contact with the lid via thermal interface material, to facilitate cooling of the one or more devices. Advantageously, the system provides a simple system for cooling of the IC and one or more devices proximate to the IC using currently employed manufacturing processes.

Exemplary Integrated Device Including a Lid System with Direct Liquid Cooling

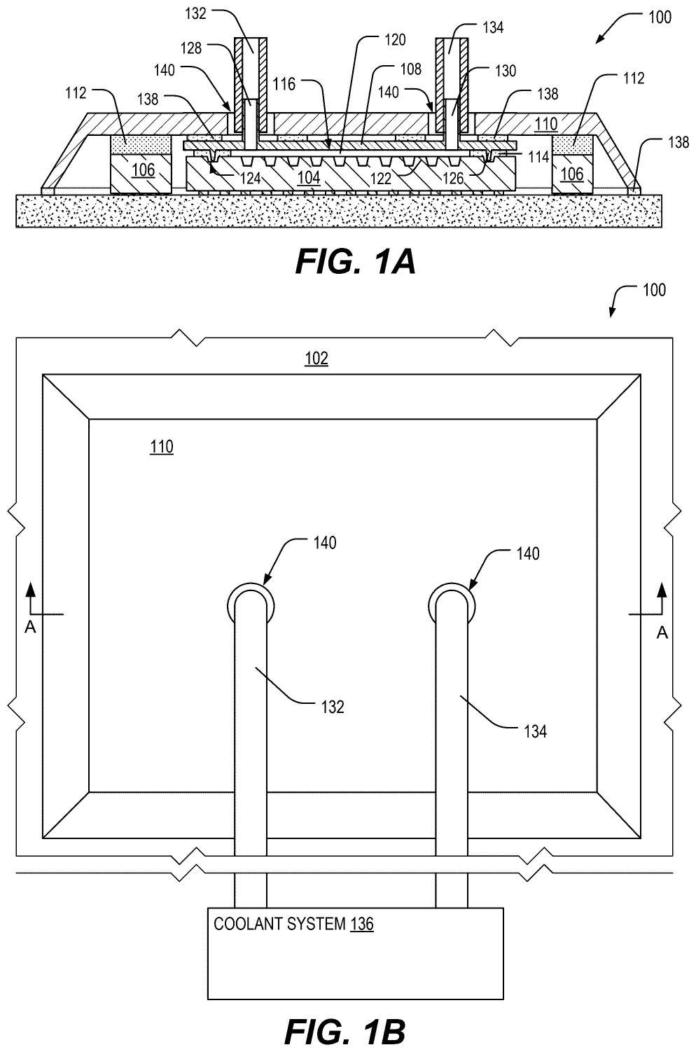

FIG. 1A illustrates a cross-sectional profile view of a system 100 that enables heat dissipation from devices of the system 100. The cross-sectional profile view illustrated in FIG. 1A is taken substantially along cutting plane A-A of the top view of the system 100 depicted in FIG. 1B.

The system 100 includes a substrate 102, a first die 104, one or more second dies 106, a manifold 108, and a lid 110. The first die 104 and the one or more second dies 106 are physically and electrically connected to the substrate 102 by electrical connectors. Each of the dies 104, 106 may be an IC and may include integrated circuitry, such as a plurality of transistors and/or other circuit elements arranged and interconnected to form logic cells, memory cells, etc. Components of the integrated circuitry can be formed in and/or over a semiconductor substrate. In some implementations, a front end-of-line (FEOL) process may be used to fabricate the integrated circuitry in and/or over the semiconductor substrate.

The first die 104 may be a high-power usage IC (e.g., a high-power IC such as a central processing unit or a graphics processing unit) to be cooled by direct liquid cooling. The one or more second dies 106 may be power management ICs, memory devices (e.g., dynamic random-access memory (DRAM), static random-access memory (SRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof), other types of ICs, or combinations thereof, that can be cooled without the need for direct liquid cooling. Some or all of the one or more second dies 106 may be thermally coupled to an integrated heat-spreader (e.g., the lid 110) by direct contact with the integrated heat-spreader or by indirect contact via a thermal interface material 112. The thermal interface material 112 may be any material capable of providing a thermally conductive interface between the lid 110 and a respective die of the one or more second dies 106, such as a thermal adhesive, a thermal grease, a gap filler pad, other material, or a combination thereof.

The first die 104 includes a support area that supports sealant 114 that couples the manifold 108 to the first die 104. The sealant 114 (e.g., an epoxy) forms a seal between the first die 104 and a first surface 116 of the manifold 108 around a heat transfer area of the first die 104 to form a chamber 120 through which a coolant fluid flows during operation of the system 100. In some implementations, the heat transfer area of the first die 104 includes one or more channels or fins 122 (e.g., posts or other structures that extend from a surface of the first die 104) that increase a surface area of the first die 104 to facilitate heat transfer from the first die 104 to a coolant fluid (e.g., distilled water or other fluid compatible with the materials of the first die 104 and the manifold 108) that is in direct contact with the first die 104 as the coolant fluid flows through the chamber 120. The channels or the fins 122 may be formed using a subtractive process that removes material from the first die 104, or may be formed using an additive process that adds material on a top surface of the first die 104.

The seal may include the sealant 114 and a tongue and groove connection between the first die 104 and the manifold 108. In an implementation, the support area of the first die 104 includes a recess 124, which corresponds to the groove of the tongue and groove connection, configured to receive a protrusion 126 extending from a bottom surface of the manifold 108, which corresponds to the tongue of the tongue and groove connection. The recess 124 may be one single recess that surrounds the heat transfer region of the first die 104 or may be one or more segments around a portion of the heat transfer region of the first die 104 and the protrusion complements the recess 124. In another implementation, the support area of the first die 104 includes a protrusion, which corresponds to the tongue of the tongue and groove connection, configured to be positioned in a recess formed in the bottom surface of the manifold 108, which corresponds to the groove of the tongue and groove connection. The protrusion may be a wall that surrounds the heat transfer region of the first die or may be one or more segments around a portion of the heat transfer region of the first die 104 and the groove in the manifold 108 complements the protrusion. In some implementations, the system 100 may include more than one tongue and groove connection. For example, two or more recesses 124 are formed in the support area of the first die 104, and the manifold includes complementary protrusions 126. In some implementations, the sealant 114 forms the seal without having a tongue and groove connection between the first die 104 and the manifold 108.

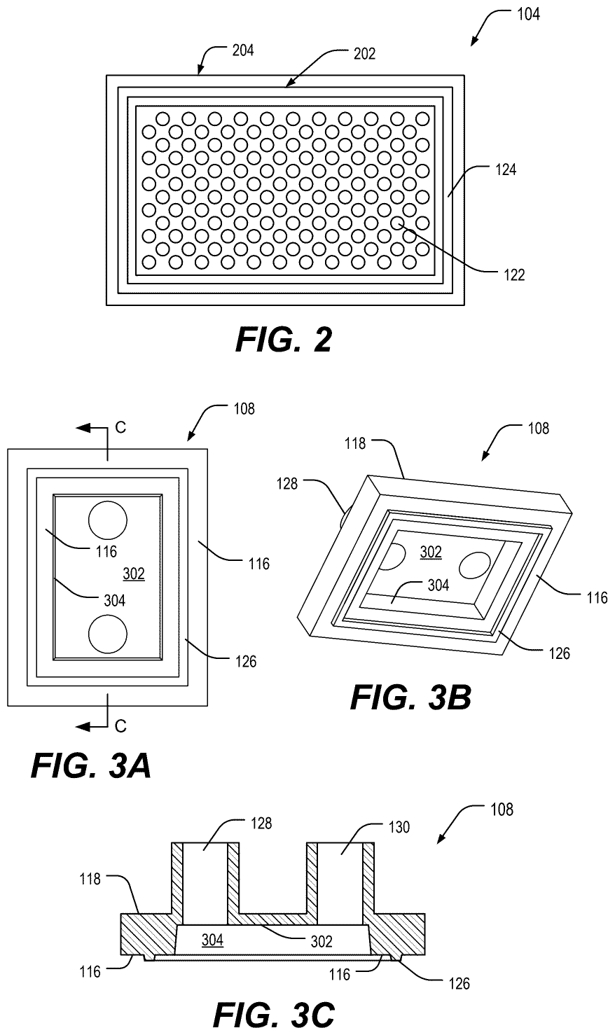

FIG. 2 depicts a top view representation of an implementation of the first die 104. The first die 104 includes a central heat transfer area 202 surrounded by a support area 204. The heat transfer area 202 includes a plurality of fins 122 extending from a surface of the heat transfer area 202. The support area 204 includes the recess 124. In some implementations, the support area may include a plurality of recesses 124. Forming one or more recesses 124 in the first die 104 and one or more corresponding protrusions 126 on the manifold 108 may advantageously improve manufacturability and yield by having a fragile component of the system 100 (e.g., the protrusion 126) on an easily manufactured and less expensive part (i.e., the manifold 108).

Returning to FIG. 1A, the system 100 includes the manifold 108. The manifold 108 may be formed of metal, polymer material, or combinations thereof. In some implementations, the manifold 108 is a unitary molded plastic member formed by injection molding. For example, the manifold 108 can include a single (e.g., unitary) member including the first surface 116 and a second surface 118 opposite the first surface 116, where the first surface 116 corresponds to a wall of the chamber 120 and fluid ports extend from the second surface 118. In FIG. 1A, the fluid ports include an inlet port 128 and an outlet port 130. To simplify injection molding of the manifold 108, the fluid ports 128, 130 are substantially straight and parallel to one another. This arrangement also simplifies assembly (e.g., attachment of the lid 110 over the manifold 108 with the fluid ports 128, 130 and/or coolant lines 132, 134 coupled to the fluid ports 128, 130 extending therethrough). Thus, forming the manifold 108 as a unitary member with the fluid ports 128, 130 extending parallel to one another and substantially perpendicular to the second surface 118 reduces manufacturing cost and simplifies tooling used (e.g., a mold used to form the manifold 108, assembly equipment, etc.).

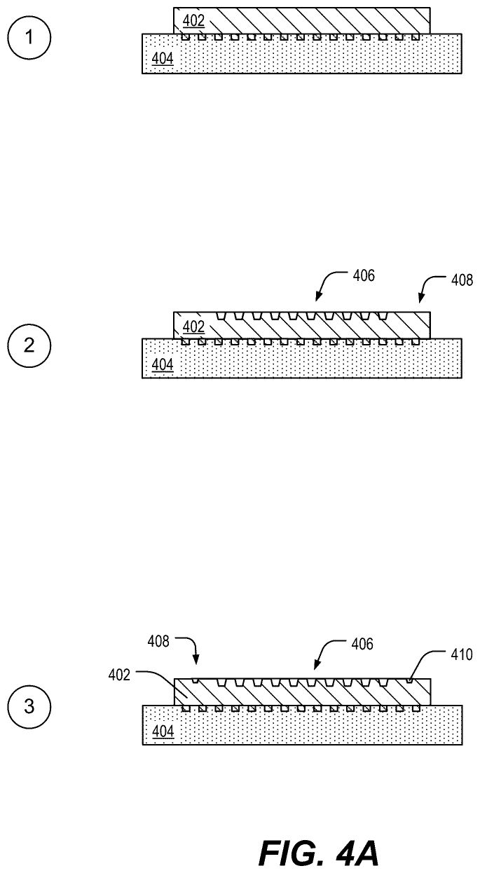

FIGS. 3A-3C depict representations of an implementation of the manifold 108. FIG. 3A depicts a bottom view representation of the manifold 108, FIG. 3B depicts a perspective view of the manifold 108, and FIG. 3C depicts a cross-sectional representation of the manifold 108. The manifold 108 includes the first surface 116, the second surface 118, the protrusion 126, a first wall 302 through which cooling fluid enters via the inlet port 128 and exits via the outlet port 130, and second walls 304. The first wall 302 and the second walls 304 are walls of the chamber 120 formed by the seal formed by the sealant 114 that couples the manifold 108 to the first die 104. The first wall 302 and the second walls 304 are configured to provide desired fluid flow characteristics through the chamber 120.

Returning to FIG. 1A, a first coolant line 132 is connected to the inlet port 128 of the manifold 108, and a second coolant line 134 is connected to the outlet port 130 of the manifold 108. The coolant lines 132, 134 may be secured to the ports 128, 130 by adhesive, clamps, one or more barbs formed on the ports 128, 130, one or more fittings, a quick-release connection system, another type of connection system, or combinations thereof.

The coolant lines 132, 134 are coupled to a coolant system 136 when the coolant system is a closed-loops system. A closed-loop system is depicted in FIG. 1B. The coolant system 136 provides the coolant fluid to the chamber 120 to implement direct liquid cooling of the first die 104. The coolant system 136 may supply the coolant fluid to a single first die, to a plurality of first dies 104 of the same electronic device, or to a plurality of first dies of two or more electronic devices. The first coolant line 132 provides the coolant fluid from the coolant system 136 to the chamber 120 through the inlet port 128; and receives, via the second coolant line 134, return coolant fluid that exits the chamber 120. The coolant system 136 may include a pump, one or more coolant reservoirs, a cooler to reduce a temperature of return coolant fluid, sensors, a control system to control operation of the coolant system and provide alerts should abnormal operation be detected, other components, or combinations thereof. In some implementations, the cooling fluid is supplied via an open-system where the coolant fluid is supplied to the inlet port 128 of the manifold from a fluid supply and all or a portion of the coolant fluid exiting through the second coolant line 134 may be used for another purpose instead of being cooled and reused as cooling fluid.

The lid 110 is adhered by adhesive 138 to the substrate 102, the manifold 108, or both. The adhesive 138 may be the same material as the sealant 114, or may be a different type of adhesive. The lid 110 may be in thermal contact with at least some of the one or more second dies 106 to facilitate cooling of the one or more second dies 106.

The lid 110 includes openings 140. The inlet port 128 and the outlet port 130 may extend through the openings 140 to facilitate attachment of the coolant lines 132, 134 to the ports 128, 130 of the manifold 108.

It should be understood that the system 100 may include additional components, other components, fewer components, or a combination thereof, to support the functionality described herein. As non-limiting examples, the substrate 102 may be a portion of a circuit board, the substrate 102 may be electrically connected to a circuit board, the system 100 may include one or more additional second dies 106 in direct contact with the lid 110, one or more additional devices connected to the substrate 102 and positioned under the lid 110 that are in not in thermal contact with the lid 110, or a combination thereof, to support the functionality and technical advantages disclosed herein.

During operation of the system 100, coolant fluid is provided from the coolant system 136 via the first coolant line 132 to the chamber 120 via the inlet port 128 of the manifold 108. A portion of the coolant fluid in the chamber is in direct contact with a heat transfer area of the first die 104 in order to maintain a temperature of the first die 104 in an operating temperature range that facilitates efficient operation of the first die 104. The coolant fluid flows through the chamber 120 to the outlet port 130 and into the second coolant line 134. In some implementations, return coolant fluid flows through the second coolant line 134 to the coolant system 136 to be cooled and reused. In other implementations, all or a portion of the coolant fluid in the second cooling line may be used for another purpose.

The system 100 provides for direct liquid cooling of the first die 104 using a simple, plug-and-play system. For example, the substrate 102 is electrically connected to a circuit board of an electronic device, and the coolant lines 132, 134 are secured to the coolant system 136 and the ports 128, 130 of the manifold 108. When the electronic device is operated, the coolant system 136 is activated to supply coolant fluid to the chamber 120 to provide direct liquid cooling of the first die 104. The use of direct liquid cooling has a technical advantage of having a small form-factor and a reduction in thermal resistance as compared to cold-plate based cooling. The use of direct liquid cooling of one or more dies can reduce the capacity of, or eliminate the need for, air conditioning systems that provide cooled air used to cool electronic devices by convection provided by air flow from one or more fans.

Exemplary Sequence for Fabricating an Integrated Device that Enables Direct Liquid Cooling of a First Die of the Integrated Device

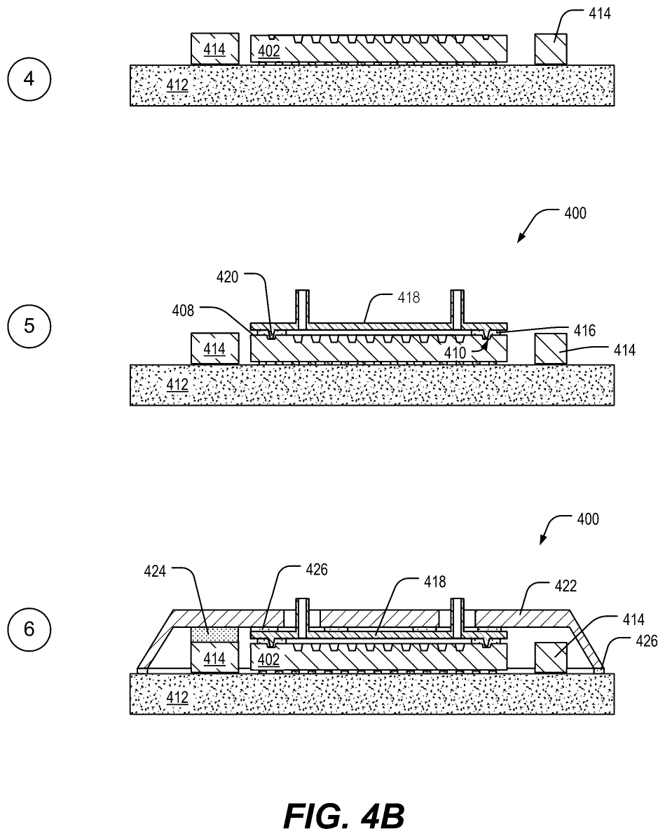

In some implementations, fabricating an integrated device 400 includes several processes. FIGS. 4A and 4B illustrate an exemplary sequence for fabricating the integrated device 400 that includes a structure to enable direct liquid cooling of a first die of the integrated device 400, to facilitate cooling of one or more devices (e.g., one or more second dies) adjacent to the first die by contact of the one or more devices with a heat spreader. In some implementations, the sequence of FIGS. 4A and 4B may be used to provide (e.g., during fabrication of) the system 100 of FIGS. 1A and 1B.

It should be noted that the sequence of FIGS. 4A and 4B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 4A and 4B.

Stage 1 of FIG. 4A illustrates a state after a first die 402 (e.g., a high-power IC such as a system-on-chip (SoC) die) is attached to a carrier 404. The first die 402 is positioned in a face-down orientation such that a front of the first die 402 with electrical connectors is coupled to the carrier 404. The first die 402 can be adhered to the carrier 404 using a releasable adhesive layer.

Although Stage 1 illustrates a single first die 402, the operations described herein can be performed for more than one first die 402 at a time. For example, the carrier 404 can be a carrier wafer such as used for reconstructed wafer level operations. In this example, a plurality (e.g., 5, 10, 50, or some other number) of first dies 402 can be coupled to the carrier 404. Additional operations can be simultaneously, or sequentially, performed on the first dies 402.

Stage 2 illustrates a state after formation of a heat transfer area 406 on the first die using a subtractive process or an additive process. As a first example, the heat transfer area 406 may be formed using a subtractive process by using one or more etching operations (e.g., a Bosch deep reactive ion etching process) guided by a patterned resist layer to form structures of the heat transfer area 406 (e.g., channels, pillars, or other formations that increase a surface area of the first die 402) in the first die 402. The surface region of the first die 402 surrounding the heat transfer area 406 is a support area 408.

As a second example, the heat transfer area 406, the support area 408, or both, may be formed using an additive process by using one or more deposition operations (e.g., chemical vapor deposition, physical vapor deposition, electroplating, or a combination thereof) guided by a patterned resist layer to form the structures of the heat transfer area 406 on the first die 402. In some implementations, a height of the first die 402 is reduced (e.g., by grinding and polishing operations) before implementation of the additive process so that the resulting first die 402 has a desired height.

Stage 3 illustrates a state after formation of an optional recess 410. The recess 410 may be formed in the support area 408 using a subtractive process by using one or more etching operations guided by a patterned resist layer to form the recess 410. In other implementations an optional protrusion may be formed on the support area 408 using an additive process by using one or more deposition operations (e.g., chemical vapor deposition, physical vapor deposition, electroplating, or a combination thereof) guided by a patterned resist layer to form the protrusion. In other implementations, the support area 408 does not include a recess 410 or a protrusion.

Stage 1 through Stage 3 have been described as performed at a die level or reconstructed wafer level (e.g., one or more first dies 402 coupled to the carrier 404). In other implementations, Stage 1 through Stage 3 may be performed at a wafer level during formation of the first dies 402. Further, in some embodiments, Stage 2 and Stage 3 can be combined such that the heat transfer area 406 and the recess 410 are formed using the same operations.

Stage 4 of FIG. 4B illustrates a state after separation of the first die 402 from the carrier 404 and electrically connecting connectors of the first die 402 to corresponding contacts of a substrate 412. For example, the carrier 404 may be heated to a temperature that melts the releasable adhesive, the first die 402 may be removed from the carrier 404, and any remaining releasable adhesive may be removed from the first die 402 using a solvent. The first die 402 may then be positioned on the substrate 412 and subjected to a reflow process to electrically connect connectors of the first die 402 to corresponding contacts of the substrate 412. One or more second dies 414 may be electrically connected to the substrate 412 adjacent to the first die 402.

Stage 5 illustrates a state after formation of a seal 416 between the support area 408 of the first die 302 and a manifold 418. For example, a bead of adhesive (e.g., epoxy) may be placed on the support area 408, on a portion of the manifold 418, or both, and the manifold 418 may be coupled to the support area 408 via the bead of adhesive. In implementations where the first die 402 includes the recess 410 and the manifold 418 includes a protrusion 420, or in implementations where the first die includes the protrusion and the manifold 418 includes a recess, a tongue and groove connection is formed by the first die 402 and the manifold 418. The tongue and groove connection may facilitate positioning the manifold 418 relative to the first die 402 and formation of the seal 416 between the manifold 418 and the first die 402. For implementations where additional cooling of the one or more second dies 414 is not required, formation of the integrated device 400 is complete after Stage 5.

For some implementations, additional cooling of a set (e.g., some or all) of the one or more second dies 414 is required. Stage 6 illustrates a state after a lid 422 (e.g., a heat spreader) is thermally coupled, directly or indirectly via thermal interface material 424, to the set of second dies 414 that require additional cooling and is adhered to the substrate 412. For example, thermal interface material 424 is applied to one or more second dies 414 of the set; adhesive 426 (e.g., epoxy) is applied to one or more locations on the substrate 412, the bottom of the lid 422, a portion of the manifold 418, or combinations thereof; and the lid 422 is coupled to the substrate 412 via the adhesive 426 to adhere the lid 422 to the substrate 412, the manifold 418, or both, and to thermally couple the lid 422 to the second dies 414 of the set. Formation of the integrated device 400 is complete after Stage 6.

Exemplary Flow Diagram of a Method for Fabricating an Integrated Device that Enables Direct Liquid Cooling of a First Die of the Integrated Device

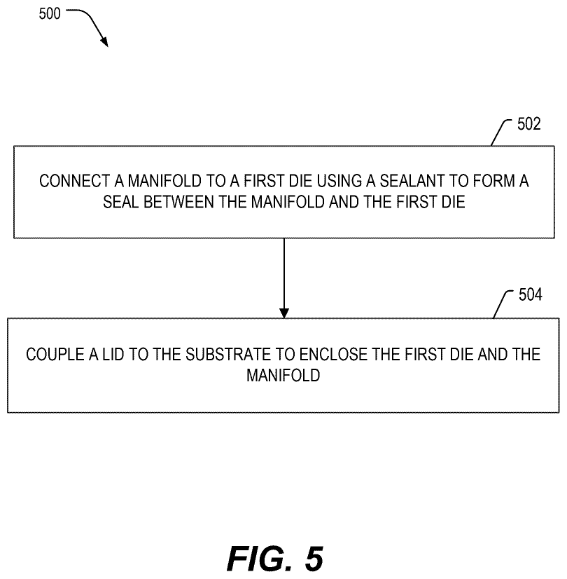

In some implementations, fabricating an IC device includes several processes. FIG. 5 illustrates an exemplary flow diagram of a method 500 of fabricating an illustrative integrated device that includes a structure that enables direct liquid cooling of a first die of the integrated device, heat dissipation of heat from one or more second dies to a heat spreader, or combinations thereof. In a particular aspect, one or more operations of the method 500 are performed by one or more processors of a fabrication system. In some implementations, operations of the method 500 may be stored as instructions by a non-transitory computer-readable storage medium, and the instructions may be executable by at least one processor to cause the at least one processor to perform operations of the method 500. In some implementations, the method 500 of FIG. 5 may be used to provide or fabricate the system 100 of FIGS. 1A and 1B or the integrated device 400 of FIG. 4B. It should be noted that the method 500 of FIG. 5 may combine one or more processes in order to simplify and/or clarify the method for providing or fabricating an integrated circuit device. In some implementations, the order of the processes may be changed or modified.

The method 500 includes connecting a manifold to a first die using a sealant to form a seal between the manifold and the first die, at block 502. The first die may be electrically connected to a substrate. The manifold includes an inlet port to a chamber between the manifold and the first die formed by the seal. The manifold also includes an outlet port from the chamber. For example, Stage 5 of FIG. 4B illustrates the manifold 418 connected to the first die 402 by an adhesive that forms the seal 416. As another example, FIGS. 1A and 1B depict the manifold 108 connected to the first die 104 by sealant 114, which forms a seal around the chamber 120 between the manifold 108 and the first die 104. The first die 104 is electrically connected to the substrate 102. The manifold 108 includes the inlet port 128 to the chamber 120 and the outlet port 130 from the chamber 120.

In some implementations, connecting the manifold to the first die includes forming a tongue and groove connection between the manifold and the die. For example, connecting the manifold 108 of FIG. 1 to the first die 104 includes applying a sealant 114 on a support area of the first die 104, to a portion of the manifold 108, or both, where the support area includes the recess 124 and the manifold 108 includes the protrusion 126; and placing the protrusion 126 in the recess 124 to couple the manifold 108 to the first die 104 via the sealant 114.

The method 500 also includes coupling a lid to the substrate to enclose the first die and the manifold, at block 504. The inlet port and the outlet port extend through openings in the lid. Coupling the lid to the substrate may include adhering the lid to the manifold with adhesive. Also, coupling the lid to the substrate may also include thermally coupling, directly or indirectly via a thermal interface material, one or more second dies to the lid. For example, Stage 6 of FIG. 4B depicts the lid 422 coupled to the substrate 412 to enclose the first die 402 and the manifold 418. As another example, FIG. 1A and FIG. 1B depict the lid 110 coupled to the substrate 102 via adhesive 138 and to the manifold via adhesive 138. Second dies 106 are thermally coupled to the lid 110 via thermal interface material 112. The inlet port 128 and the outlet port 130 of the manifold 108 extend through openings 140 in the lid 110.

In some implementations, the method 500 also includes coupling a first coolant line of a coolant system to the inlet port, and coupling a second coolant line of the coolant system to the outlet port. The coolant system is configured to flow coolant fluid through the chamber to exchange heat with the first die. For example, the system 100 of FIGS. 1A and 1B depicts the first coolant line 132 coupled to the inlet port 128 and the coolant system 136, the second coolant line 134 coupled to the outlet port 130 and the coolant system 136, and the coolant system is configured to flow coolant fluid through the chamber 120 so that the coolant fluid directly contacts a heat transfer area 202 of the first die, which is depicted in FIG. 2, to cause transfer of heat from the heat transfer area 202 of the first die 104 to cooling fluid in the chamber 120. A portion of the cooling fluid in the chamber 120 directly contacts the heat transfer area 202 of the first die 104.

### Exemplary Electronic Devices

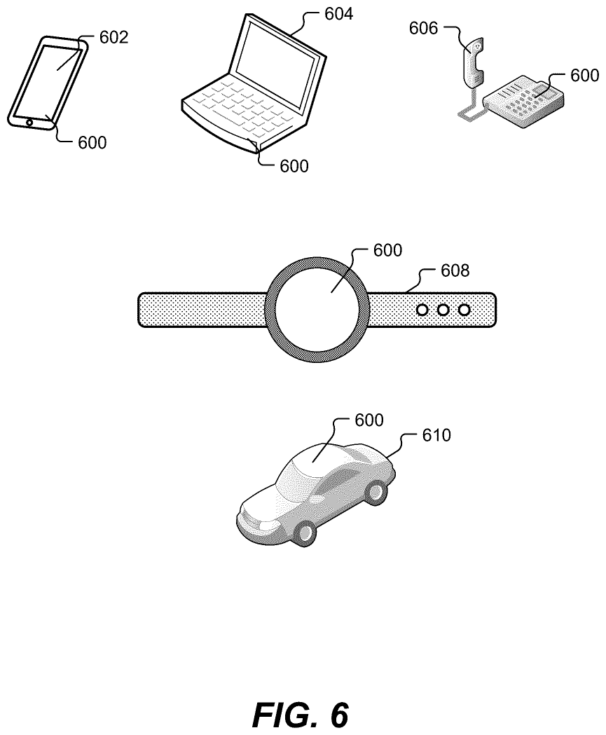

FIG. 6 illustrates various electronic devices that may include or be integrated with the system 100. For example, a mobile phone device 602, a laptop computer device 604, a fixed location terminal device 606, a wearable device 608, or a vehicle 610 (e.g., an automobile or an aerial device) may include a device 600. The device 600 can include, for example, the system 100, and/or any other integrated device described herein. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-6 may be rearranged and/or combined into a single component, process, feature or function or embodied in several components, processes, or functions. Additional elements, components, processes, and/or functions may also be added without departing from the disclosure. It should also be noted FIGS. 1A-6 and its corresponding description in the present disclosure is not limited to dies and/or ICs. In some implementations, FIGS. 1A-6 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a coolant system, a heat dissipating device, and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a substrate; a first die physically and electrically connected to the substrate; wherein the manifold includes a first surface, an inlet port configured as an entry for fluid into a chamber formed between the first die and the manifold, and an outlet port configured to provide an exit from the chamber for the fluid; and a sealant connecting the first die to the first surface of the manifold to form a seal between the first die and the manifold.

Example 2 includes the device of Example 1, wherein a portion of the first die includes a plurality of fins to increase a surface area of the first die.

Example 3 includes the device of Example 1 or Example 2, wherein the manifold is formed of a polymer material.

Example 4 includes the device of Examples 3, wherein the manifold is a unitary, molded member.

Example 5 includes the device of any of Examples 1 to 4, wherein the first die includes a recess that forms a groove of a tongue and groove connection, and wherein the manifold includes a protrusion that forms a tongue of the tongue and groove connection.

Example 6 includes the device of Examples 1 to 5, wherein walls of the chamber include a first wall and second walls of the manifold.

According to Example 7, a system includes a substrate; a first die physically and electrically connected to the substrate; a manifold, wherein the manifold includes an inlet port configured as an entry for fluid into a chamber formed between the first die and the manifold, and wherein the manifold includes an outlet port configured to provide an exit from the chamber for the fluid; a seal for the chamber between the first die and the manifold; and a lid coupled to the substrate, wherein the inlet port and the outlet port extend through openings in the lid.

Example 8 includes the system of Example 7 and further includes one or more second dies coupled to the substrate and enclosed by the lid.

Example 9 includes the system of Example 8 and further includes thermal interface material coupled to at least one of the one or more second dies and coupled to the lid.

Example 10 includes the system of any of Examples 7 to 9, wherein the lid is adhered to the manifold.

Example 11 includes the system of any of Examples 7 to 10, wherein a portion of the first die includes a plurality of fins to increase a surface area of the first die.

Example 12 includes the system of any of Examples 7 to 11, wherein the manifold is formed of plastic and the lid is formed of metal.

Example 13 includes the system of any of Examples 7 to 12, wherein the seal comprises sealant and a tongue and groove connection between the first die and the manifold.

Example 14 includes the system of Examples 13, wherein the manifold includes a channel that forms a groove of the tongue and groove connection, and wherein the first die includes a protrusion that forms a tongue of the tongue and groove connection.

According to Example 15, a method of forming an integrated circuit device, the method includes connecting a manifold to a first die using a sealant to form a seal between the manifold and the first die, wherein the first die is electrically connected to a substrate, wherein the manifold includes an inlet port to a chamber between the manifold and the first surface formed by the seal, and wherein the manifold includes an outlet port from the chamber; and coupling a lid to the substrate to enclose the first die and the manifold, wherein the inlet port and the outlet port extend through openings in the lid.

Example 16 includes the method of Example 15 and further includes: coupling a first coolant line of a coolant system to the inlet port; and coupling a second coolant line of the coolant system to the outlet port, wherein the coolant system is configured to flow coolant fluid through the chamber to exchange heat with the first die.

Example 17 includes the method of Example 15 or Example 16, wherein a portion of the first die includes a plurality of fins to increase a surface area of the first die, and wherein the portion is located in the chamber.

Example 18 includes the method of any of Examples 15 to 17, wherein said connecting the manifold to the first die comprises: applying the sealant on a support area of the first die, to a portion of the manifold, or both, wherein the support area includes a channel and the manifold includes a protrusion; and placing the protrusion in the channel to couple the manifold to the first die via the sealant.

Example 19 includes the method of any of Examples 15 to 18, wherein said coupling the lid to the substrate further comprises adhering the lid to the manifold.

Example 20 includes the method of any of Examples 15 to 19, wherein said coupling the lid to the substrate further comprises thermally coupling, via thermal interface material, one or more second dies to the lid.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate;
a first die physically and electrically connected to the substrate;
a manifold, wherein the manifold includes a first surface, an inlet port configured as an entry for fluid into a chamber formed between the first die and the manifold, and an outlet port configured to provide an exit from the chamber for the fluid; and
a sealant connecting the first die to the first surface of the manifold to form a seal between the first die and the manifold.

2. The device of claim 1, wherein a portion of the first die includes a plurality of fins to increase a surface area of the first die.

3. The device of claim 1, wherein the manifold is formed of a polymer material.

4. The device of claim 3, wherein the manifold is a unitary, molded member.

5. The device of claim 1, wherein the first die includes a recess that forms a groove of a tongue and groove connection, and wherein the manifold includes a protrusion that forms a tongue of the tongue and groove connection.

6. The device of claim 1, wherein walls of the chamber include a first wall and second walls of the manifold.

7. A system comprising:
a substrate;
a first die physically and electrically connected to the substrate;
a manifold, wherein the manifold includes an inlet port configured as an entry for fluid into a chamber formed between the first die and the manifold, and wherein the manifold includes an outlet port configured to provide an exit from the chamber for the fluid;
a seal for the chamber between the first die and the manifold; and
a lid coupled to the substrate, wherein the inlet port and the outlet port extend through openings in the lid.

8. The system of claim 7, further comprising one or more second dies coupled to the substrate and enclosed by the lid.

9. The system of claim 8, further comprising thermal interface material coupled to at least one of the one or more second dies and coupled to the lid.

10. The system of claim 7, wherein the lid is adhered to the manifold.

11. The system of claim 7, wherein a portion of the first die includes a plurality of fins to increase a surface area of the first die.

12. The system of claim 7, wherein the manifold is formed of plastic and the lid is formed of metal.

13. The system of claim 7, wherein the seal comprises sealant and a tongue and groove connection between the first die and the manifold.

14. The system of claim 13, wherein the manifold includes a channel that forms a groove of the tongue and groove connection, and wherein the first die includes a protrusion that forms a tongue of the tongue and groove connection.

15. A method of forming an integrated circuit device, the method comprising:
connecting a manifold to a first die using a sealant to form a seal between the manifold and the first die, wherein the first die is electrically connected to a substrate, wherein the manifold includes an inlet port to a chamber between the manifold and the first die formed by the seal, and wherein the manifold includes an outlet port from the chamber; and
coupling a lid to the substrate to enclose the first die and the manifold, wherein the inlet port and the outlet port extend through openings in the lid.

16. The method of claim 15, further comprising:
coupling a first coolant line of a coolant system to the inlet port; and
coupling a second coolant line of the coolant system to the outlet port, wherein the coolant system is configured to flow coolant fluid through the chamber to exchange heat with the first die.

17. The method of claim 15, wherein a portion of the first die includes a plurality of fins to increase a surface area of the first die, and wherein the portion is located in the chamber.

18. The method of claim 15, wherein said connecting the manifold to the first die comprises:
applying the sealant on a support area of the first die, to a portion of the manifold, or both, wherein the support area includes a recess and the manifold includes a protrusion; and
placing the protrusion in the recess to couple the manifold to the first die via the sealant.

19. The method of claim 15, wherein said coupling the lid to the substrate further comprises adhering the lid to the manifold.

20. The method of claim 15, wherein said coupling the lid to the substrate further comprises thermally coupling, via thermal interface material, one or more second dies to the lid.
